(19) United States
(12) Patent Application Publication
(10) Pub. No.: US 2025/0066913 A1
(43) Pub. Date: Feb. 27, 2025

(54) SEAM PERFORMANCE IMPROVEMENT USING HYDROXYLATION FOR GAPFILL

(71) Applicant: Applied Materials, Inc., Santa Clara, CA (US)

(72) Inventors: Supriya Ghosh, San Jose, CA (US); Susmit Singha Roy, Campbell, CA (US); Abhijit Basu Mallick, Sunnyvale, CA (US); Nitin K. Ingle, San Jose, CA (US); Diwakar Kedlaya, San Jose, CA (US); Priya Chouhan, Fremont, CA (US)

(73) Assignee: Applied Materials, Inc., Santa Clara, CA (US)

(21) Appl. No.: 18/455,508

(22) Filed: Aug. 24, 2023

(51) Int. Cl. C23C 16/455; C23C 16/40; H01J 37/32; H01L 21/02

(52) U.S. Cl. CPC C23C 16/45536; C23C 16/401; H01J 37/32449; H01J 37/32825; H01L 21/02164; H01L 21/02274; H01L 21/0228; H01J 2237/332

(57) ABSTRACT

Methods of filling a feature on a semiconductor substrate may include performing a process to fill the feature on the semiconductor substrate by repeatedly performing first operations. First operations can include providing a silicon-containing precursor. First operations can include contacting the substrate with the silicon-containing precursor to form a silicon-containing material within the feature defined on the substrate. First operations can include purging the semiconductor processing chamber. First operations can include providing an oxygen-and-hydrogen-containing precursor. First operations can include contacting the substrate with the oxygen-and-hydrogen-containing precursor to form a silicon-and-oxygen-containing material within the feature defined on the substrate.

### TECHNICAL FIELD

The present technology relates to methods of semiconductor processing. More specifically, the present technology relates methods of forming materials on semiconductor structures.

### BACKGROUND

Integrated circuits are made possible by processes which produce intricately patterned material layers on substrate surfaces. Producing patterned material on a substrate requires controlled methods for forming and removing material. As device sizes continue to reduce, and device complexity continues to increase, producing structures has become increasingly complex. Developing structures may take many more operations to produce the complex patterning and material integration. Additionally, complex patterning and material integration at intersections between materials, including similar materials, may take more operations to prevent potential deformations or unwanted formations.

Thus, there is a need for improved systems and methods that can be used to produce high quality devices and structures. These and other needs are addressed by the present technology.

### SUMMARY

In some embodiments, a method of filling a feature on a semiconductor substrate can include performing a process to fill the feature on the semiconductor substrate in a semiconductor processing chamber, wherein the process comprises repeatedly performing first operations including: providing a silicon-containing precursor, contacting the substrate with the silicon-containing precursor to form a silicon-containing material within the feature defined on the substrate, purging the semiconductor processing chamber, providing an oxygen-and-hydrogen-containing precursor, and contacting the substrate with the oxygen-and-hydrogen-containing precursor to form a silicon-and-oxygen-containing material within the feature defined on the substrate.

In some embodiments, the process to fill the feature can further include repeatedly performing second operations prior to repeatedly performing first operations, wherein both the first operations and the second operations are done at about a first pressure level, the second operations include: providing the silicon-containing precursor, contacting the substrate with the silicon-containing precursor to form a silicon-containing material within the feature defined on the substrate, purging the semiconductor processing chamber, providing an oxygen-containing precursor, and contacting the substrate with the oxygen-containing precursor to form a silicon-and-oxygen-containing material within the feature defined on the substrate. In some embodiments, providing the oxygen-and-hydrogen-containing precursor can cause a gap in the feature to close by causing a first side of the silicon-and-oxygen-containing material within the feature to bond with a second side of the silicon-and-oxygen-containing material within the feature. In some embodiments, forming the silicon-containing material within the feature can include forming an atomic layer of silicon on an exposed surface of the feature. In some embodiments, wherein forming the silicon-and-oxygen-containing material within the feature can include providing oxygen to the atomic layer of silicon.

In some embodiments, a method of filling a feature on a semiconductor substrate can include performing a process to fill the feature on the semiconductor substrate in a semiconductor processing chamber, wherein the process comprises repeatedly performing first operations including: providing a silicon-containing precursor, contacting the substrate with the silicon-containing precursor to form a silicon-containing material within the feature defined on the substrate, purging the semiconductor processing chamber, providing an oxygen-containing precursor, contacting the substrate with the oxygen-containing precursor to form a silicon-and-oxygen-containing material within the feature defined on the substrate, providing an oxygen-and-hydrogen-containing precursor, and contacting the silicon-and-oxygen-containing material with the oxygen-and-hydrogen-containing precursor.

In some embodiments, the process to fill the feature can further include repeatedly performing second operations prior to repeatedly performing first operations, the second operations can include: providing the silicon-containing precursor, contacting the substrate with the silicon-containing precursor to form a silicon-containing material within the feature defined on the substrate, purging the semiconductor processing chamber, providing the oxygen-containing precursor, and contacting the substrate with the oxygen-containing precursor to form a silicon-and-oxygen-containing material within the feature defined on the substrate. In some embodiments, contacting the silicon-and-oxygen-containing precursor with the oxygen-and-hydrogen-containing precursor can cause a gap in the feature to close by causing a first side of the silicon-and-oxygen-containing material within the feature to bond with a second side of the silicon-and-oxygen-containing material within the feature.

In some embodiments, a method of filling a feature on a semiconductor substrate can include performing a process to fill the feature on the semiconductor substrate in a semiconductor processing chamber, wherein the process comprises repeatedly performing first operations including: providing a silicon-containing precursor, contacting the substrate with the silicon-containing precursor to form a silicon-containing material within the feature defined on the substrate, purging the semiconductor processing chamber, providing an oxygen-and-hydrogen-containing precursor, and contacting the substrate with the oxygen-and-hydrogen-containing precursor to form a silicon-and-oxygen-containing material within the feature defined on the substrate. The process to fill the feature can further include repeatedly performing second operations at a second pressure level after repeatedly performing first operations, the second operations including: providing an oxygen-and-hydrogen-containing precursor, and contacting the silicon-and-oxygen-containing material with the oxygen-and-hydrogen-containing precursor.

In some embodiments, the second operations, prior to providing the oxygen-and-hydrogen-containing precursor, can further include: providing the silicon-containing precursor, contacting the silicon-and-oxygen-containing material with the silicon-containing precursor to form a silicon-containing material within the feature, and purging the semiconductor processing chamber. In some embodiments, contacting the silicon-and-oxygen-containing precursor with the oxygen-and-hydrogen-containing precursor can cause a gap in the feature to close by causing a first side of the silicon-and-oxygen-containing material within the feature to bond with a second side of the silicon-and-oxygen-containing material within the feature. In some embodiments, the first pressure level can be about 2 Torr or greater. In some embodiments, the second pressure level can be about atmospheric pressure.

In any embodiments, any and all of the following features can be implemented in any combination and without limitation. In some embodiments, the oxygen-and-hydrogen-containing precursor can include a plasma. In some embodiments, the oxygen-and-hydrogen-containing precursor can include a gas. In some embodiments, the oxygen-containing precursor can include a plasma. In some embodiments, the oxygen-containing precursor can include a gas. In some embodiments, the process can be performed at a temperature greater than or about 400° C. In some embodiments, the feature can be characterized by an aspect ratio of greater than or about 10:1. In some embodiments, the oxygen-and-hydrogen-containing precursor can include O₂ and H₂. In some embodiments, the oxygen-and-hydrogen-containing precursor can include H₂O₂. In some embodiments, the oxygen-and-hydrogen-containing precursor can include H₂O.

### BRIEF DESCRIPTION OF THE DRAWINGS

A further understanding of the nature and advantages of the disclosed technology may be realized by reference to the remaining portions of the specification and the drawings.

FIG. 1 shows a schematic cross-sectional view of an exemplary plasma system according to some embodiments of the present technology.

FIGS. 2A-2D show exemplary schematic cross-sectional structures in which material layers are produced according to some embodiments of the present technology.

FIGS. 3A-3B show exemplary schematic cross-sectional structures in which material layers are produced according to some embodiments of the present technology.

FIG. 4 shows an exemplary schematic cross-sectional diagram in which material layers are included according to some embodiments of the present technology.

FIG. 5 shows an exemplary schematic cross-sectional diagram in which material layers are included according to some embodiments of the present technology.

FIG. 6 shows an exemplary schematic cross-sectional diagram in which material layers are included according to some embodiments of the present technology.

FIG. 7 shows operations in a semiconductor processing method according to some embodiments of the present technology.

FIG. 8 shows operations in a semiconductor processing method according to some embodiments of the present technology.

FIG. 9 shows operations in a semiconductor processing method according to some embodiments of the present technology.

Several of the figures are included as schematics. It is to be understood that the figures are for illustrative purposes, and are not to be considered of scale unless specifically stated to be of scale. Additionally, as schematics, the figures are provided to aid comprehension and may not include all aspects or information compared to realistic representations, and may include exaggerated material for illustrative purposes.

In the appended figures, similar components and/or features may have the same reference label. Further, various components of the same type may be distinguished by following the reference label by a letter that distinguishes among the similar components. If only the first reference label is used in the specification, the description is applicable to any one of the similar components having the same first reference label irrespective of the letter.

### DETAILED DESCRIPTION

Silicon material may be used in semiconductor device manufacturing for a number of structures and processes. In gap filling operations, some processing may utilize plasma-enhanced deposition under process conditions in attempt to increase the directionality of the deposition, which may allow the deposited material to better fill features on the substrate. However, in some deposition processes, the deposited material in certain kinds of features may be characterized by seams when the deposited material meets up with other deposited material. For example, if a feature represents a significantly large depth to width ratio (meaning the feature is deep but the size of an opening for the feature is relatively small in width), deposited material from the sides of the feature can meet up and create seams.

As feature sizes continue to shrink, depositions may be challenged for narrow features, which may be further characterized by higher aspect ratios. For example, as material is deposited material in a feature with a high aspect ratio, seams can form between the deposited material on a first side of the feature and the deposited material on a second side of the feature. Seams can also be referred to as gaps or voids. Seams represent that the deposited material on the sides of the features do not bond when the deposited material on the sides meet. These seams may not be noticeable by tools because the seams can be on the atomic level. Nonetheless, an etchant used on the deposited material (such as a buffer oxide etchant on a silicon oxide deposited material) can expose and/or demonstrate that there is a seam between the deposited material on the sides of the feature.

The present technology may overcome these limitations by performing an atomic layer deposition of material that may limit or prevent sidewall coverage during deposition, allowing improved fill operations to be performed. Additionally, a hydroxylation operation may be performed to bond the sides of deposited material in a feature to reduce and/or eliminate seams. Bonding the sides of deposited material in a feature to eliminate seams can also be referred to as gapfilling the seams. Gapfilling the seams can also be referred to as backfill or large area gap fill.

Although the remaining disclosure will routinely identify specific deposition processes utilizing the disclosed technology, and will describe one type of semiconductor processing chamber, it will be readily understood that the processes described may be performed in any number of semiconductor processing chambers. Additionally, the present technology may be applicable to any number of semiconductor processes, beyond the exemplary process described below. Accordingly, the technology should not be considered to be so limited as for use with these specific deposition processes or chambers alone. The disclosure will discuss one possible chamber that may be used to perform processes according to embodiments of the present technology before methods of semiconductor processing according to the present technology are described.

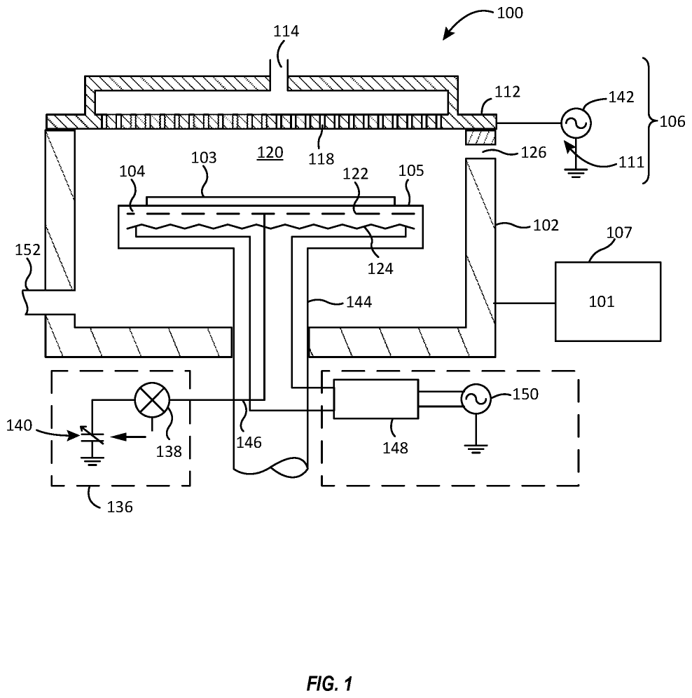

FIG. 1 shows a cross-sectional view of an exemplary processing chamber 100 according to some embodiments of the present technology. The figure may illustrate an overview of a system incorporating one or more aspects of the present technology, and/or which may be specifically configured to perform one or more operations according to embodiments of the present technology. Additional details of chamber 100 or methods performed may be described further below. Chamber 100 may be utilized to form film layers, etch material layers, form other material layers, or a combination thereof, although it is to be understood that deposition and etch methods may similarly be performed in any chamber within which deposition and etch processes may occur. The processing chamber 100 may include a chamber body 102, a substrate support 104 disposed inside the chamber body 102, and a lid assembly 106 coupled with the chamber body 102 and enclosing the substrate support 104 in a processing volume 120. A substrate 103 may be provided to the processing volume 120 through an opening 126, which may be conventionally sealed for processing using a slit valve or door. The substrate 103 may be seated on a surface 105 of the substrate support during processing. In some embodiments, the substrate support 104 may be rotatable, along a vertical axis, where a shaft 144 of the substrate support 104 may be located, or may be stationary. Alternatively, the substrate support 104 may be lifted up to rotate as necessary during a deposition process.

A gas distributor 112 may define apertures 118 for distributing process precursors into the processing volume 120. The gas distributor 112 may be coupled with a first source of electric power 142, such as an RF generator, RF power source, DC power source, pulsed DC power source, pulsed RF power source, or any other power source that may be coupled with the processing chamber. In some embodiments, the first source of electric power 142 may be an RF power source.

The gas distributor 112 may be a conductive gas distributor or a non-conductive gas distributor. The gas distributor 112 may also be formed of conductive and non-conductive components. For example, a body of the gas distributor 112 may be conductive while a face plate of the gas distributor 112 may be non-conductive. The gas distributor 112 may be powered, such as by the first source of electric power 142 as shown in FIG. 1, or the gas distributor 112 may be coupled with ground in some embodiments.

A first electrode 122 may be coupled with the substrate support 104. The first electrode 122 may be embedded within the substrate support 104 or coupled with a surface of the substrate support 104. The first electrode 122 may be a plate, a perforated plate, a mesh, a wire screen, or any other distributed arrangement of conductive elements. The first electrode 122 may be a tuning electrode and may be coupled with a tuning circuit 136 by a conduit 146, for example a cable having a selected resistance, such as 50 ohms, for example, disposed in the shaft 144 of the substrate support 104. The tuning circuit 136 may have an electronic sensor 138 and an electronic controller 140, which may be a variable capacitor. The electronic sensor 138 may be a voltage or current sensor and may be coupled with the electronic controller 140 to provide further control over plasma conditions in the processing volume 120.

A second electrode 124, which may be a bias electrode and/or an electrostatic chucking electrode, may be coupled with the substrate support 104. The second electrode may be coupled with a second source of electric power 150 through a filter 148, which may be an impedance matching circuit. The second source of electric power 150 may be DC power, pulsed DC power, RF bias power, a pulsed RF source or bias power, or a combination of these or other power sources. In some embodiments, the second source of electric power 150 may be an RF bias power. The substrate support 104 may also include one or more heating elements configured to heat the substrate to a processing temperature, which may be between about 25° C. and about 800° C. or greater.

The lid assembly 106 and substrate support 104 of FIG. 1 may be used with any processing chamber for plasma or thermal processing. In operation, the processing chamber 100 may afford real-time control of plasma conditions in the processing volume 120, such as via a system controller 101 which may be contained within a processor 107. The substrate 103 may be disposed on the substrate support 104, and process gases may be flowed through the lid assembly 106 using an inlet 114 according to any desired flow plan. Gases may exit the processing chamber 100 through an outlet 152. Electric power may be coupled with the gas distributor 112 to establish a plasma in the processing volume 120. The substrate may be subjected to an electrical bias using the second electrode 124 in some embodiments.

Upon energizing a plasma in the processing volume 120, a potential difference may be established between the plasma and the first electrode 122. The electronic controller 140 may then be used to adjust the flow properties of the ground paths represented by the tuning circuit 136. A set point may be delivered to the tuning circuit 136 to provide independent control of deposition rate and of plasma density uniformity from center to edge. In embodiments where the electronic controllers may both be variable capacitors, the electronic sensors may adjust the variable capacitors to maximize deposition rate and minimize thickness non-uniformity independently.

Tuning circuit 136 may have a variable impedance that may be adjusted using the electronic controller 140. Where the electronic controller 140 is a variable capacitor, the capacitance range of each of the variable capacitors, may be chosen to provide an impedance range. This range may depend on the frequency and voltage characteristics of the plasma, which may have a minimum in the capacitance range of each variable capacitor. Hence, when the capacitance of the electronic controller 140 is at a minimum or maximum, impedance of the tuning circuit 136 may be high, resulting in a plasma shape that has a minimum aerial or lateral coverage over the substrate support. When the capacitance of the electronic controller 140 approaches a value that minimizes the impedance of the tuning circuit 136, the aerial coverage of the plasma may grow to a maximum, effectively covering the entire working area of the substrate support 104. As the capacitance of the electronic controller 140 deviates from the minimum impedance setting, the plasma shape may shrink from the chamber walls and aerial coverage of the substrate support may decline.

The electronic sensor 138 may be used to tune the tuning circuit 136 in a closed loop. A set point for current or voltage, depending on the type of sensor used, may be installed in each sensor, and the sensor may be provided with control software that determines an adjustment to the electronic controller 140 to minimize deviation from the set point. Consequently, a plasma shape may be selected and dynamically controlled during processing. It is to be understood that, while the foregoing discussion is based on electronic controller 140, which may be a variable capacitor, any electronic component with adjustable characteristic may be used to provide tuning circuit 136 with adjustable impedance.

Processing chamber 100 may be utilized in some embodiments of the present technology for processing methods that may include bottom-up deposition of materials for semiconductor structures. It is to be understood that the chamber described is not to be considered limiting, and any chamber that may be configured to perform operations as described may be similarly used.

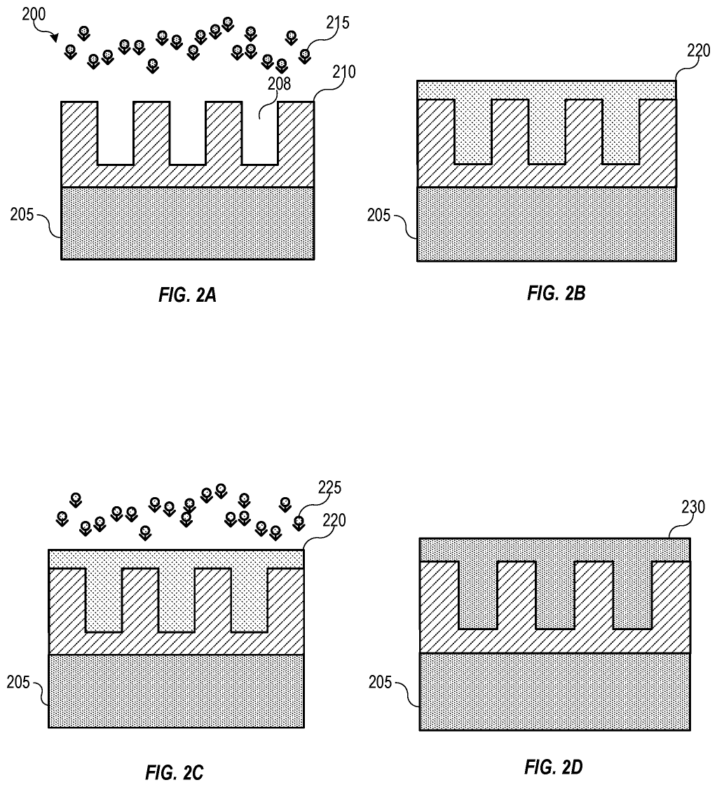

Processing chamber 100 may be utilized in some embodiments of the present technology for processing methods that may include formation, etching, or conversion of materials for semiconductor structures. It is to be understood that the chamber described is not to be considered limiting, and any chamber that may be configured to perform operations as described may be similarly used. FIGS. 2A-2D schematically illustrate exemplary operations in processing methods according to some embodiments of the present technology. The methods may be performed in a variety of processing chambers and on one or more mainframes or tools, including processing chamber 100 described above. The processing methods may include a number of optional operations, which may or may not be specifically associated with some embodiments of methods according to the present technology. For example, many of the operations are described in order to provide a broader scope of the structural formation, but are not critical to the technology, or may be performed by alternative methodology as would be readily appreciated. It is to be understood that the figures illustrate only partial schematic views, and a structure 200 or a substrate 205 may contain any number of additional materials and features having a variety of characteristics and aspects as shown in the figures.

The substrate 205 may include any number of materials used in semiconductor processing. The substrate material may be or include silicon, germanium, dielectric materials including silicon oxide or silicon nitride, metal materials, or any number of combinations of these materials. The substrate 205 may include one or more substrate features formed in the substrate 205. The substrate 205 may include one or more materials 210 in which one or more features may be formed. The features may be characterized by any shape or configuration according to the present technology. In some embodiments, the features may be or include a trench structure 208 or aperture formed within the substrate. In some embodiments, the features may be characterized by any aspect ratios, or the height-to-width ratio of the structure, although in some embodiments the materials may be characterized by larger aspect ratios, which may not allow seam free or void free deposition utilizing conventional technology or methodology. For example, in some embodiments the aspect ratio of any layer of an exemplary structure may be greater than or about 10:1, greater than or about 11:1, greater than or about 12:1, greater than or about 13:1, greater than or about 14:1, greater than or about 15:1, greater than or about 16:1, or greater. Additionally, the features may be characterized by a reduced width, such as less than or about 2.0 microns, less than or about 1.9 microns, less than or about 1.8 microns, less than or about 1.7 microns, less than or about 1.6 microns, less than or about 1.5 microns, less than or about 1.4 microns, less than or about 1.3 microns, less than or about 1.2 microns, less than or about 1.1 microns, less than or about 1.0 microns, less than or about 0.9 microns, less than or about 0.8 microns, less than or about 0.7 microns, less than or about 0.6 microns, less than or about 0.5 microns, less than or about 0.4 microns, less than or about 0.3 microns, less than or about 0.2 microns, less than or about 0.1 microns, or less, including any fraction of any of the stated numbers. As such, the features may be characterized with a height, such as less than or about 20.0 microns, less than or about 19.0 microns, less than or about 18.0 microns, less than or about 17.0 microns, less than or about 16.0 microns, less than or about 15.0 microns, less than or about 14.0 microns, less than or about 13.0 microns, less than or about 12.0 microns, less than or about 11.0 microns, less than or about 10.0 microns, less than or about 9.0 microns, less than or about 8.0 microns, less than or about 7.0 microns, less than or about 6.0 microns, less than or about 5.0 microns, less than or about 4.0 microns, less than or about 3.0 microns, less than or about 2.0 microns, less than or about 1.0 microns, less than or about 0.8 microns, or less, including any fraction of any of the stated numbers. This combination of high aspect ratios and minimal widths may frustrate many conventional deposition operations to bond the deposited material on one side of the feature to the deposited material on another side of the feature.

The methods described herein may include additional operations prior to initiation of the operations to gapfill the seam. For example, additional processing operations may include forming structures on a semiconductor substrate 205, which may include both forming and removing material. For example, transistor structures, memory structures, or any other structures may be formed. Prior processing operations may be performed in the chamber in the methods for gapfilling seams described herein may be performed, or processing may be performed in one or more other processing chambers prior to delivering the substrate into the semiconductor processing chamber or chambers in which the methods for gapfilling seams described herein may be performed. Regardless, the methods for gapfilling seams described herein may optionally include delivering a semiconductor substrate 205 to a processing region of a semiconductor processing chamber, such as processing chamber 100 described above, or other chambers that may include components as described above. The substrate 205 may be deposited on a substrate support, which may be a pedestal such as substrate support 104, and which may reside in a processing region of the semiconductor processing chamber, such as a processing volume.

Embodiments of the present disclosure may form silicon-containing and/or silicon-and-oxygen-containing material through atomic layer deposition. The material may be formed by alternatingly providing precursors such that the material intermittently forms. To deposit silicon-and-oxygen-containing material, the precursors may include silicon and oxygen. The precursor including silicon may be referred to as a silicon-containing precursor. The precursor including oxygen may be referred to as an oxygen-containing precursor. In some embodiments, a silicon-and-oxygen-containing material may be formed through atomic layer deposition. To incorporate oxygen, the precursors may further include oxygen. For example, an oxygen-containing precursor may be intermittently provided during the formation. Alternatively, the silicon-containing precursor may further include oxygen. For example, the silicon-containing precursor may be a silicon-and-oxygen-containing precursor.

Embodiments of the present disclosure may to gapfill seams formed between sides of silicon-and-oxygen-containing material along the sides of a feature. In some embodiments, gapfilling seams may be done through atomic layer deposition. Gapfilling seams may be done by alternatingly providing precursors such that the material intermittently forms. One precursor can include silicon and may be referred to as a silicon-containing precursor. Another precursor may include oxygen and hydrogen and may be referred to as an oxygen-and-hydrogen-containing precursor. In some embodiments, gapfilling seams may be done through an annealing or annealing-like process. The oxygen-and-hydrogen-containing precursor can be introduced into the semiconductor chamber while the semiconductor substrate 205 is annealing in the processing chamber 100 or in another processing chamber.

In embodiments, the silicon-containing precursor may be any silicon-containing material useful in semiconductor processing, such as in atomic layer deposition processes. Exemplary silicon-containing precursors may be or include, but are not limited to, silane, disilane, or other aminosilanes, or other organosilanes including cyclohexasilanes, silicon tetrafluoride, silicon tetrachloride, dichlorosilane, tetraethyl orthosilicate (TEOS), tetramethyldisiloxane (TMDSO), hexamethyldisiloxane (HMDSO), hexamethyldisilazane (HMDSN), and silicon tetrakis (ethylmethyamide) (TEMASi), alkylaminosilane, trisilylamine, alkylaminodisilane, alkylsilane, alkyloxysilane, alkylsilanol, and alkyloxysilanolas well as any other silicon-containing precursors that may be used in silicon-containing material formation. In some embodiments, the silicon-containing precursor may include a halogen, such as chlorine, bromine, iodine, or any other halogen. Additional silicon-containing precursors may be or include any of the following materials:

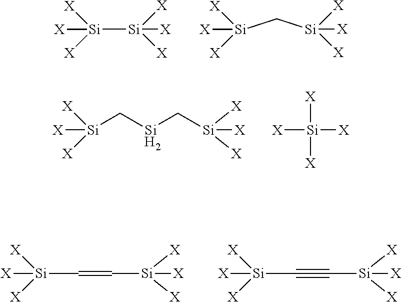

In the above materials, each X may be independently selected from chlorine, bromine, iodine, hydrogen, OR, NR₂, NCO, NCS, or CN, where R may be an alkyl.

The oxygen-containing precursor may be any oxygen-containing material useful in semiconductor processing, such as in atomic layer deposition processes. For example, the oxygen-containing precursor may be molecular oxygen (O₂), ozone (O₃), N₂O, and/or other similar materials. In embodiments, in order to maintain oxygen content in the formed material, the oxygen-containing precursor may be diluted with another precursor such as an inert precursor. The oxygen-containing precursor may be less than or about 50% based on the oxygen-containing precursor and the inert precursor.

The oxygen-and-hydrogen-containing precursor may be any oxygen-and-hydrogen-containing material useful in semiconductor processing, such as in atomic layer deposition processes. For example, the oxygen-and-hydrogen-containing precursor may be water or steam (H₂O), hydrogen peroxide (H₂O₂), or a combination of molecular hydrogen (H₂) and molecular oxygen (O₂). In embodiments, in order to maintain oxygen content in the formed material, the oxygen-containing precursor may be diluted with another precursor such as an inert precursor. The oxygen-and-hydrogen-containing precursor may be less than or about 50% based on the oxygen-and-hydrogen-containing precursor and the inert precursor. For example, argon gas or other similar gases may be included as a carrier gas with the hydrogen-containing precursor.

In some embodiments, an oxygen-containing precursor can refer to a precursor that does not contain hydrogen. In some embodiments, an oxygen-containing precursor can be referred to an oxygen-and-not-hydrogen-containing precursor.

The methods described herein for gapfilling seams may include providing a first precursor to the semiconductor processing chamber, such as a processing region of the semiconductor processing chamber. Optionally, a plasma of the first precursor may be generated. It is also contemplated that a plasma of the first precursor may be generated prior to providing the plasma of the first precursor to the semiconductor processing chamber. In some embodiments, the first precursor is a silicon-containing precursor. Referring to FIG. 2A, the first precursor may have at least one reactive group that can form a bond with a group attached to a surface of the substrate 205 or one or more materials 210 in the processing region. Molecules of the first precursor 215 may react with the surface groups to form bonds linking the first precursor molecule to the surface of the substrate 205 or one or more materials 210. The reactions between molecules of the first precursor 215 and the groups on the surface of the substrate 205 or one or more materials 210 may continue until most or all the surface groups are bonded to a reactive group on molecules of the first precursor 215. As shown in FIG. 2B, a first portion of a silicon-containing material 220 may be formed. The formation of the silicon-and-oxygen-containing material 220 may block further reaction between molecules of the first precursor 215 in the first precursor effluent and the substrate 205 or one or more materials 210.

The first precursor may remain in the processing region for a period of time to nearly or completely form the silicon-containing material 220. To form the silicon-containing material according to embodiments of the present technology, precursors may be delivered in alternating pulses to grow the material. In some embodiments, the pulse time of the first precursor may be greater than or about 0.5 seconds, greater than or about 1 second, greater than or about 2 seconds, greater than or about 3 seconds, greater than or about 4 seconds, greater than or about 5 seconds, greater than or about 10 seconds, greater than or about 20 seconds, greater than or about 40 seconds, greater than or about 60 seconds, greater than or about 80 seconds, greater than or about 100 seconds, or more.

The methods described herein may also include an operation to purge or remove the first precursor from the processing region following the formation of the silicon-containing material 220. The methods described herein may include halting a flow of the first precursor prior to purging the first precursor from the semiconductor processing chamber. The first precursor may be removed by pumping them out of the processing region for a period of time ranging from about 10 seconds to about 100 seconds. Additional exemplary time ranges may include about 20 seconds to about 50 seconds, and 25 seconds to about 45 seconds, among other exemplary time ranges. However, in some embodiments, increased purge time may begin to remove reactive sites, which may reduce uniform formation. Accordingly, in some embodiments the purge may be performed for less than or about 60 seconds, and may be performed for less than or about 50 seconds, less than or about 40 seconds, less than or about 30 seconds, or less. In some embodiments, a purge gas may be introduced to the processing region to assist in the removal of the effluents. Exemplary purge gases include helium and nitrogen, among other purge gases.

After the removal of the first precursor, a second precursor may be provided to the semiconductor processing chamber as shown in FIG. 2C. Optionally, a plasma of the second precursor may be generated. It is also contemplated that a plasma of the second precursor may be generated prior to providing the plasma of the second precursor to the semiconductor processing chamber. The second precursor may have at least one reactive group that can form bonds with unreacted reactive groups of the first precursor that formed the silicon-containing material 220. In some embodiments, the second precursor is an oxygen-and-hydrogen-containing precursor. Molecules of the second precursor 225 may react with the unreacted reactive groups of the first precursor to form bonds linking molecules of the second precursor 225 to molecules of the first precursor 215. The reactions between molecules of the second precursor 225 and molecules of the first precursor 215 may continue until most or all the unreacted reactive groups on molecules of the first precursor 215 have reacted with molecules of the second precursor 225. As shown in FIG. 2D, the contact between the second precursor and the silicon-containing material 220 may form a silicon-and-oxygen-containing material 230, such as SiO. The formation of the silicon-and-oxygen-containing material 230 may block further reaction between molecules of the second precursor 225 in the second precursor effluent and the silicon-and-oxygen-containing material 220.

Similar to the first precursor, the second precursor may remain in the processing region for a period of time to nearly or completely form the silicon-and-oxygen-containing material 230. As previously discussed, to form silicon-and-oxygen-containing material according to embodiments of the present technology, precursors may be delivered in alternating pulses to grow the material. In some embodiments, the pulse time of the second precursor may be greater than or about 0.5 seconds, greater than or about 1 second, greater than or about 2 seconds, greater than or about 3 seconds, greater than or about 4 seconds, greater than or about 5 seconds, greater than or about 10 seconds, greater than or about 20 seconds, greater than or about 40 seconds, greater than or about 60 seconds, greater than or about 80 seconds, greater than or about 100 seconds, or more.

In some embodiments, the first precursor may be pulsed for longer periods of time than the second precursor. By increasing the residence time of the first precursor, improved adhesion may be produced across the substrate 205 or one or more materials 210. The second precursor may then more readily react with the ligands of the first precursor, and thus the second precursor may be pulsed for less time, which may improve throughput. For example, in some embodiments, the second precursor may be pulsed for less than or about 90% of the time the first precursor is pulsed. The second precursor may also be pulsed for less than or about 80% of the time the first precursor is pulsed, less than or about 70% of the time the first precursor is pulsed, less than or about 60% of the time the first precursor is pulsed, less than or about 50% of the time the first precursor is pulsed, less than or about 40% of the time the first precursor is pulsed, less than or about 30% of the time the first precursor is pulsed, or less.

The methods described herein can also include an operation to purge or remove the second precursor effluents from the processing region following the formation of the silicon-containing material 230. The methods described herein may include halting a flow of the second precursor prior to pursing the second precursor. The second precursor may be removed by pumping them out of the processing region for a period of time ranging from about 10 seconds to about 100 seconds. Additional exemplary time ranges may include about 20 seconds to about 50seconds, and 25 seconds to about 45 seconds, among other exemplary time ranges. In some embodiments, a purge gas may be introduced to the processing region to assist in the removal of the effluents. Exemplary purge gases include helium and nitrogen, among other purge gases.

In embodiments, there may be a determination of whether a target thickness of the as-deposited material on the substrate 205 or one or more materials 210 has been achieved following one or more cycles of forming the silicon-and-oxygen-containing material 230. If a target thickness of the as-deposited material has not been achieved, another cycle of providing the first precursor and second precursor may be performed. If a target thickness of the as-deposited material has been achieved, another cycle of providing the first precursor and second precursor may not be started. Exemplary numbers of cycles for the formation of the silicon-and-oxygen-containing material 230 may include 1 cycle, or may include greater than 2 cycles, 5 cycles, 10 cycles, 25 cycles, 50 cycles, 100 cycles, 1000 cycles, 2000 cycles, 3000 cycles, 4000 cycles, 5000 cycles, 6000 cycles, 7000 cycles, 8000 cycles, 9000 cycles, 10000 cycles or more. Additional exemplary ranges for the number of cycles may include 50 cycles to 2000 cycles, 50 cycles to 1000 cycles, and 100 cycles to 750 cycles, 1000 to 2000 cycles, 2000 to 3000 cycles, 3000 to 4000 cycles, 4000 to 5000 cycles, 5000 to 6000 cycles, 6000 to 7000 cycles, 7000 to 8000 cycles, 8000 to 9000 cycles, 9000 to 10000 cycles, and/or any combination of these ranges.

For example, some embodiments may use between 6000 and 8000 cycles for a 1 μm wide gap structure. Exemplary ranges of target thickness to discontinue further cycles of forming silicon-and-oxygen-containing material 230 include less than or about 1.0 microns. Additional exemplary thickness ranges may include less than or about 1.0 microns, less than or about 0.9 microns, less than or about 0.8 microns, less than or about 0.7 microns, less than or about 0.6 microns, less than or about 0.5 microns, less than or about 0.4 microns, less than or about 0.3 microns, less than or about 0.2 microns, less than or about 0.1 microns, or less, including any fraction of any of the stated numbers.

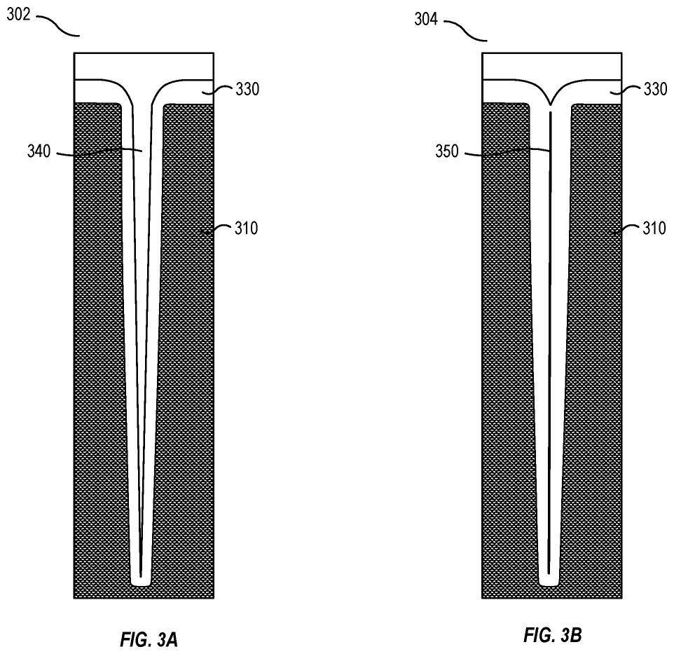

FIGS. 3A-3B schematically illustrate how a seam may be formed during processing methods according to some embodiments of the present technology. Cross-section 302 and cross-section 304 schematically illustrate how a seam 350 is formed by the silicon-and-oxygen containing material 330 (for example, the silicon-and-oxygen-containing material 230 of FIG. 2) deposited unto the one or more materials 310 (for example, the one or more materials 210 of FIG. 2). In FIG. 3A, a space 340 can be seen between the two sides of the silicon-and-oxygen-containing material 330 deposited into the feature. The silicon-and-oxygen-containing material 330 can be roughly uniform across the surface of the one or more materials 310.

In FIG. 3B, as more silicon-and-oxygen-containing material 330 is deposited, a seam 350 can be formed such that the two sides of the silicon-and-oxygen-containing material 330 do not bond. The seam 350 can be formed because the layers of the silicon-and-oxygen-containing material 330 build up from the sides of the feature. As noted above, the seam 350 may not be noticeable because the seam may be on the atomic and/or molecular level. However, if an etchant (for example, a buffer oxide etchant that etches the silicon-and-oxygen-containing material 330) is applied to the silicon-and-oxygen-containing material 330 along the seam 350, the seam 350 can become noticeable as material from the silicon-and-oxygen-containing material 330 around the seam 350 is etched away.

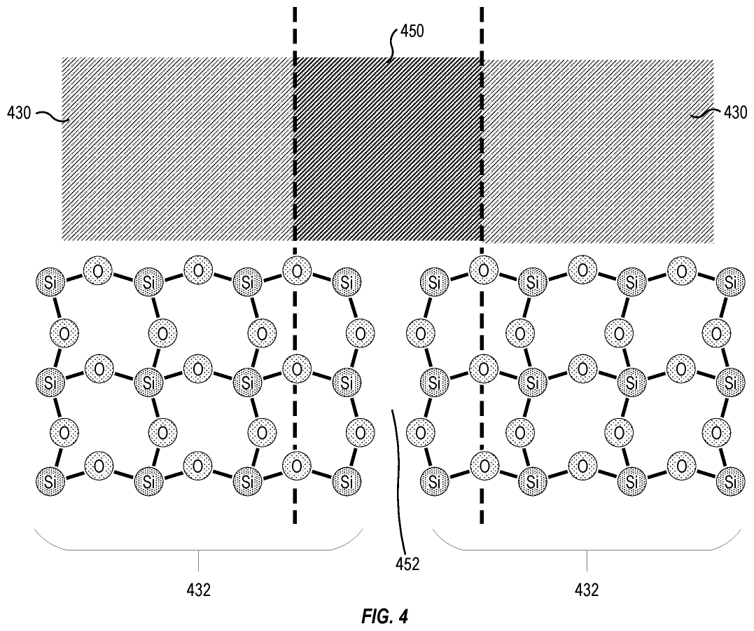

FIG. 4 illustrates an example diagram of a seam at the atomic and/or molecular level. As the silicon-and-oxygen-containing material 430 (for example, the silicon-and-oxygen-containing material 230 of FIG. 2) is deposited onto the one or more materials (for example, the one or more materials 210 of FIG. 2), a seam 450 forms between the two sides of the silicon-and-oxygen-containing material 430. The silicon-and-oxygen-containing lattice 432 represents an atomic diagram of the silicon-and-oxygen-containing material 430. Similarly, the seam 452 represents the seam 450 that forms between the two sides of the silicon-and-oxygen-containing lattice 432. The seam 452 can be any size, for example, on the approximate order of one or two atoms and/or bonds between atoms or on the order of nanometers or microns. Essentially because there is a lack of bonds between the two sides of the silicon-and-oxygen-containing material 430, a seam 450 forms.

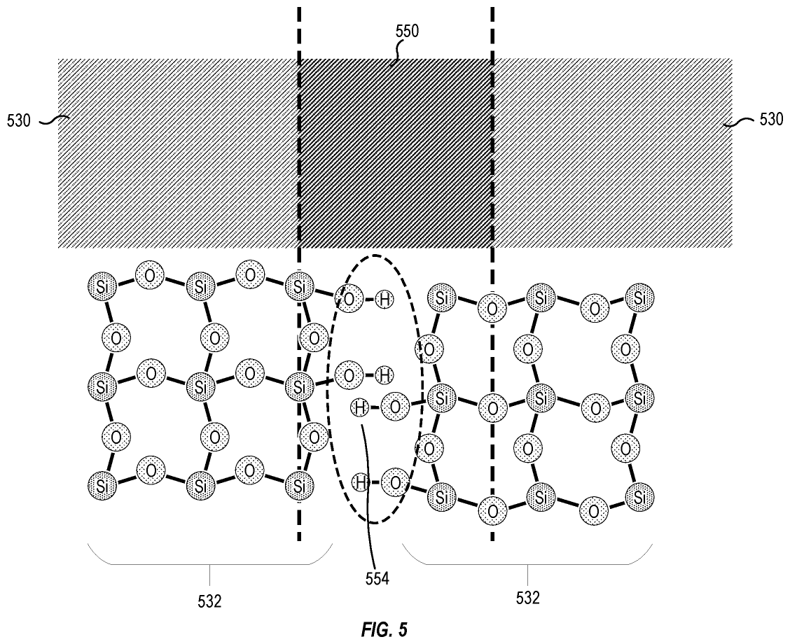

FIG. 5 illustrates an example diagram of a seam at the atomic and/or molecular level as the second precursor described above is provided to the semiconductor processing chamber as shown in FIG. 2C. As the second precursor (for example, an oxygen-and-hydrogen-containing precursor) is provided to the semiconductor processing chamber, the second precursor can contact and/or react with the silicon-and-oxygen-containing lattice 532 (for example, the silicon-and-oxygen-containing lattice 432 of FIG. 4). The contacting and/or reacting of the second precursor with the silicon-and-oxygen-containing lattice 532 can cause oxygen atoms in the silicon-and-oxygen-containing lattice 532 along the seam 554 to pick up hydrogen atoms. In this way, the sides of the silicon-and-oxygen-containing lattice 532 go from a stable and unreactive state to a reactive state as the silicon-and-oxygen-containing lattice 532 picks up hydrogen atoms. More specifically, usually the oxygen atoms of the silicon-and-oxygen-containing lattice 532 pick up the hydrogen atoms and become reactive. This picking up of the hydrogen atoms can be referred to as surface activation and/or hydroxylation. Surface activation and/or hydroxylation can begin the gapfilling process of the seam 550 between the silicon-and-oxygen-containing material 530.

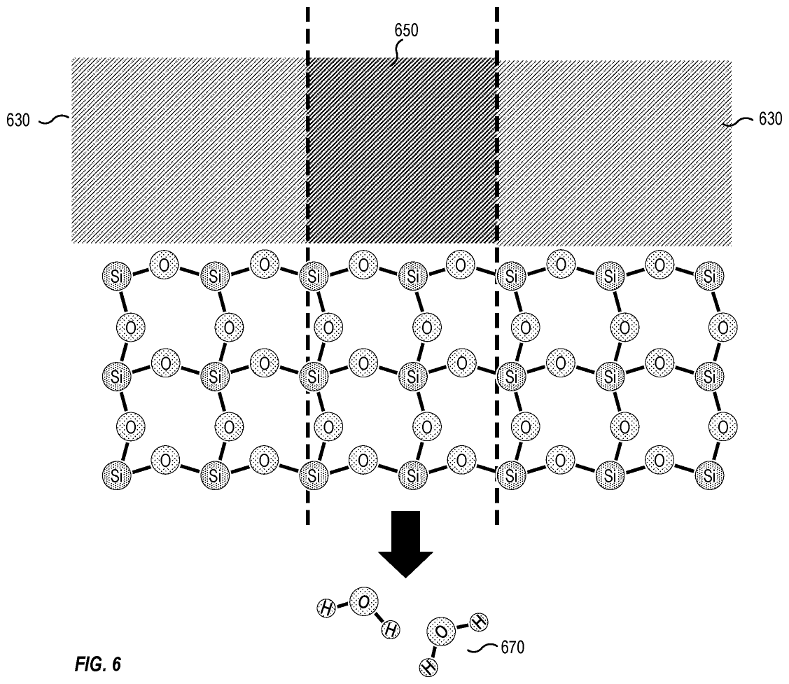

FIG. 6 illustrates an example diagram of a seam at the atomic and/or molecular level as the seam is gapfilled. During or after the second precursor is provided to the semiconductor processing chamber, the seam 650 (for example, the seam 450 of FIG. 4) between the silicon-and-oxygen-containing material 630 (for example, the silicon-and-oxygen-containing material 430 of FIG. 4) can be gapfilled. The surface activation and/or hydroxylation of the two sides of the silicon-and-oxygen-containing material 630 can allow the two sides to bond such that no seam or gap exists. The surface activation and/or hydroxylation of the two sides uses some energy from the temperature of the silicon-and-oxygen-containing material 630, the processing chamber, and/or the oxygen-and-hydrogen-containing precursor. The bonding of the two sides of the silicon-and-oxygen-containing material 630 can be referred to as cross-linking the silicon and oxygen atoms of the two sides of the silicon-and-oxygen-containing material 630. When the two sides bond, oftentimes an oxygen-and-hydrogen byproduct is produced, for example H₂O. This byproduct can escape the seam.

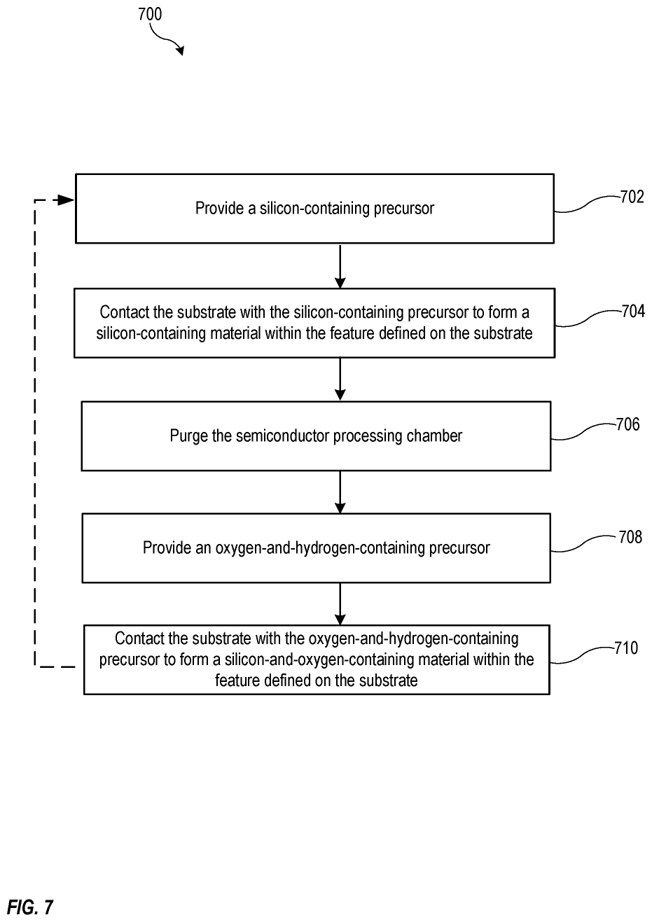

FIG. 7 illustrates an example flowchart 700 of a method of filling a feature on a semiconductor substrate as described herein. This method may be carried out by the controller that generates the signals for controlling the processing chamber and other elements as illustrated above in FIGS. 2-6. This method may be carried out by a controller having processors that execute instructions to perform these operations.

The method may include performing a process to fill the feature on the semiconductor substrate in a semiconductor processing chamber. The process can include repeatedly performing first operations as described herein. For example, the first operations can be repeated for a number of cycles as described herein. Additionally, parts of the first operations can be repeated for different numbers of cycles such that one part of the first operations can be repeated for a first number of cycles while a second part of the first operations can be repeated for a second number of cycles. In some embodiments, the feature can be characterized by an aspect ratio of greater than or about 10:1 as described herein.

The first operations may include providing a silicon-containing precursor (702) to a semiconductor processing chamber (for example, the processing chamber 100 of FIG. 1) as described in relation to at least FIGS. 2A-2D. The silicon-containing precursor can be a first precursor as described herein.

The first operations may include contacting the substrate with the silicon-containing precursor to form a silicon-containing material within the feature defined on the substrate (704) as described herein. Forming the silicon-containing material within the feature can include forming an atomic layer of silicon on an exposed surface of the feature. The exposed surface of the feature can include two or more sides of the feature, for example sides that are opposite of each other.

The first operations may include purging the semiconductor processing chamber (706) as described herein. Purging the semiconductor processing chamber of the silicon-containing precursor can allow for the use of other precursors during the process to fill the feature on the semiconductor substrate.

The first operations may include providing an oxygen-and-hydrogen-containing precursor (708) as described herein. Providing the oxygen-and-hydrogen-containing precursor can cause a gap in the feature to close by causing a first side of the silicon-and-oxygen-containing material within the feature to bond with a second side of the silicon-and-oxygen-containing material within the feature as described in relation to at least FIGS. 3A-3B. In some embodiments, the oxygen-and-hydrogen-containing precursor can include O₂ and H₂. In some embodiments, the oxygen-and-hydrogen-containing precursor can include H₂O₂. In some embodiments, the oxygen-and-hydrogen-containing precursor can include H₂O. In some embodiments, the oxygen-and-hydrogen-containing precursor can include, mostly include, or solely be a plasma. In some embodiments, the oxygen-and-hydrogen-containing precursor can include, mostly include, or solely be a gas.

The first operations may include contacting the substrate with the oxygen-and-hydrogen-containing precursor to form a silicon-and-oxygen-containing material within the feature defined on the substrate (710) as described herein. Forming the silicon-and-oxygen-containing material within the feature can include providing oxygen to the atomic layer of silicon.

As previously discussed, plasma effluents of the first precursor, the second precursor, and/or the oxygen-containing precursor may be generated. In embodiments, only plasma effluents of the oxygen-and-hydrogen-containing precursor and/or the oxygen-containing precursor may be generated, while the silicon-containing precursor may be plasma-free. By generating plasma effluents of one or more precursors, directionality of the effluent may be increased, which may encourage deposition of material that is seam free and void free. When plasma is generated, one or more inert precursors, such as argon, helium, or nitrogen, may be provided with the precursor to assist in generating plasma effluents as well as distribute the precursor. The plasma of the inert precursor may be a capacitively coupled plasma (CCP) plasma, a plasma formed in a remote plasma source (RPS), or a microwave plasma.

After forming the silicon-and-oxygen-containing material 230, the methods described herein may include performing a post-formation treatment. The post-formation treatment may include providing an inert precursor to the semiconductor processing chamber, generating plasma effluents of the inert precursor, and contacting the silicon-and-oxygen-containing material 230 with plasma effluents of the inert precursor. The inert precursor may be or include any inert precursors, such as argon, helium, or nitrogen. Similar to the optional plasma of the first precursor, the second precursor, and/or the third precursor, the plasma of the inert precursor may be a capacitively coupled plasma (CCP) plasma, a plasma formed in a remote plasma source (RPS), or a microwave plasma. The plasma effluents of the inert precursor may regenerate reactive species on surfaces of exposed materials, which may allow for continued growth to occur. The plasma effluents of the inert precursor may densify the material by outgassing hydrogen.

The formation rate of the silicon-and-oxygen-containing material 230 may depend on the temperature of the substrate 205, the temperature of the processing chamber, and/or the temperature of the precursors that flow into the processing region. Exemplary temperatures for the substrate, processing chamber, and/or precursors during the operations described herein may be greater than or about 50° C., greater than or about 75° C., greater than or about 100° C., greater than or about 125° C., greater than or about 150° C., greater than or about 175° C., greater than or about 200° C., greater than or about 250° C., greater than or about 300° C., greater than or about 350° C., greater than or about 400° C., greater than or about 425° C., greater than or about 450° C., greater than or about 475° C., greater than or about 500° C., greater than or about 525° C., greater than or about 550° C., greater than or about 575° C., greater than or about 600° C., greater than or about 625° C., greater than or about 650° C., greater than or about 675° C., greater than or about 700° C., greater than or about 725° C., greater than or about 750° C., greater than or about 775° C., greater than or about 800° C., greater than or about 825° C., greater than or about 850° C., greater than or about 875° C., greater than or about 900° C., greater than or about 925° C., greater than or about 950° C., greater than or about 975° C., greater than or about 1000° C., or higher. In some embodiments, exemplary temperatures can range from 400° C.-1000° C. In some embodiments, exemplary temperatures can range from 400° C.-700° C. In some embodiments, exemplary temperatures can range from 600° C.-1000° C. By maintaining the substrate temperature elevated, such as above or about 400° C. in some embodiments, an increased number of nucleation sites may be available along the substrate 205, which may improve formation and reduce void formation by improving coverage at each location.

The formation rate of the silicon-and-oxygen-containing material 230 may also depend on the pressure in the processing chamber. Exemplary pressures in the processing region may range from about 1 Torr to about 100 Torr. In some embodiments, the pressures in the processing region may range from 2 to 10 Torr. In embodiments, the pressure may be less than or about 10 Torr, such as less than or about 9 Torr, less than or about 8 Torr, less than or about 7 Torr, less than or about 6 Torr, less than or about 5 Torr, less than or about 4 Torr, less than or about 3 Torr, less than or about 2 Torr, less than or about 1 Torr, or less. In some embodiments, part of the processes in the processing chamber can be done at about atmospheric pressure as described herein.

The increased density of the materials of the present technology may result in an increased wet etch rate ratio (WERR). WERR may be defined as the relative etch rate of the silicon-and-oxygen-containing material, such as in Å/min, in a particular etchant, such as dilute HF, compared to the etch rate of a thermally-grown silicon oxide material formed on the same substrate. A WERR of 1.0 means the material in question has the same etch rate as a thermal oxide material, while a WERR of less than 1 means the silicon-oxygen-containing material etches at a slower rate than thermal oxide. In embodiments, the WERR of the silicon-and-oxygen-containing material may be characterized by a WERR of less than or about 1, such as less than or about 0.9, less than or about 0.8, less than or about 0.7, less than or about 0.6, less than or about 0.5, less than or about 0.4, less than or about 0.3, less than or about 0.2, less than or about 0.1, or less.

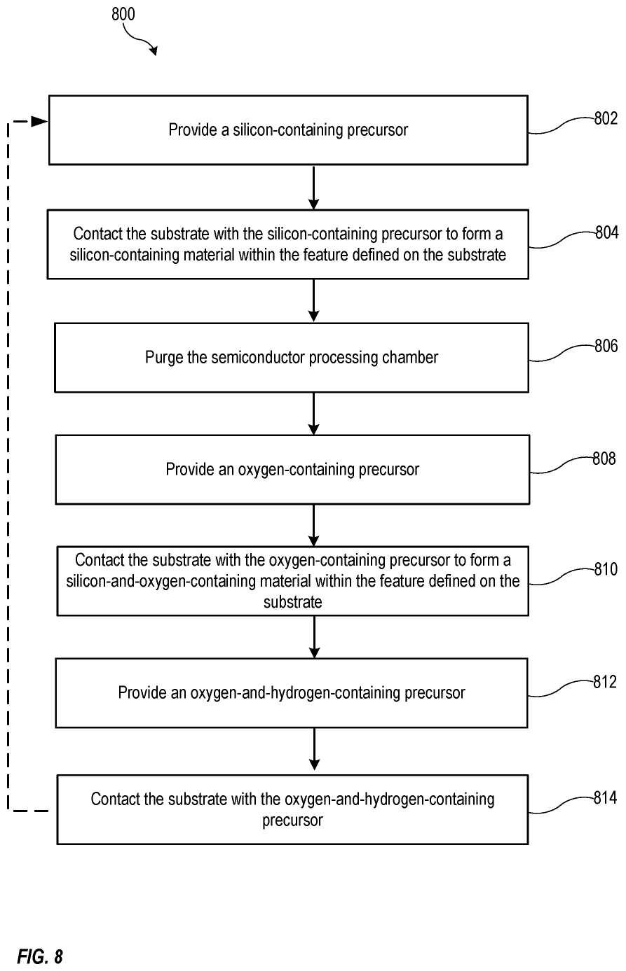

In relation to FIG. 8, as well as FIGS. 2A-2D and 3A-3B, the methods described herein for gapfilling seams may, in some embodiments, include providing a third precursor to the semiconductor processing chamber, such as a processing region of the semiconductor processing chamber. In some embodiments, the third precursor is an oxygen-containing precursor as described above. Providing a third precursor to the semiconductor processing chamber can be used to form the silicon-and-oxygen-containing material (for example, the silicon-and-oxygen-containing material 220 of FIG. 2) in the feature. Providing the second precursor to the semiconductor processing chamber can be used to gapfill the seams (also referred to as closing the gap in the feature) as well as to form the silicon-and-oxygen-containing material in the feature. In some embodiments, all description herein related to the use of the second precursor is also applicable to the third precursor. For example, description herein related to providing the second precursor to the semiconductor processing chamber is also descriptive of the providing of the third precursor to the semiconductor processing chamber.

In some embodiments, a plasma of the third precursor may be generated. It is also contemplated that a plasma of the third precursor may be generated prior to providing the plasma of the third precursor to the semiconductor processing chamber.

In some embodiments, the third precursor is provided to the semiconductor processing chamber prior to the second precursor. For example, after the removal of the first precursor, the third precursor may be provided to the semiconductor processing chamber in much the same way as the second precursor is provided, as shown in relation to FIG. 2C. Then, after the removal of the third precursor, the second precursor may be provided to the semiconductor processing chamber as described in relation to FIG. 2C. In this way, an additional precursor (the third precursor) can be provided between the first precursor and the second precursor such that the method for gapfilling includes providing three precursors.

In relation to the embodiments described herein using a third precursor, the third precursor may have at least one reactive group that can form bonds with unreacted reactive groups of the first precursor that formed the silicon-containing material 220. Molecules of the third precursor may react with the unreacted reactive groups of the first precursor to form bonds linking molecules of the third precursor to molecules of the first precursor 215. The reactions between molecules of the third precursor and molecules of the first precursor 215 may continue until most or all the unreacted reactive groups on molecules of the first precursor 215 have reacted with molecules of the third precursor. As shown in FIG. 2D, the contact between the third precursor and the silicon-containing material 220 may form a silicon-and-oxygen-containing material 230, such as SiO. The formation of the silicon-and-oxygen-containing material 230 may block further reaction between molecules of the third precursor 225 in the third precursor effluent and the silicon-and-oxygen-containing material 220.

In some embodiments, the third precursor may be provided to the semiconductor chamber after the second precursor is provided to the semiconductor processing chamber. For example, after the second precursor is provided to the semiconductor processing chamber or after the removal of the second precursor, the third precursor may be provided to the semiconductor processing chamber as described above in relation to the second precursor and as shown in FIG. 2C. The third precursor may have at least one reactive group that can form bonds with unreacted reactive groups of the first precursor that formed the silicon-containing material 220. Molecules of the third precursor may react with the unreacted reactive groups of the first precursor to form bonds linking molecules of the third precursor to molecules of the first precursor 215. The reactions between molecules of the third precursor and molecules of the first precursor 215 may continue until most or all the unreacted reactive groups on molecules of the first precursor 215 have reacted with molecules of the third precursor. As shown in FIG. 2D, the contact between the third precursor and the silicon-containing material 220 may form a silicon-and-oxygen-containing material 230, such as SiO. The formation of the silicon-and-oxygen-containing material 230 may block further reaction between molecules of the third precursor 225 in the third precursor effluent and the silicon-and-oxygen-containing material 220.

Similar to the first precursor and the second precursor, the third precursor may remain in the processing region for a period of time to nearly or completely form the silicon-and-oxygen-containing material 230. As previously discussed, to form silicon-and-oxygen-containing material according to embodiments of the present technology, precursors may be delivered in alternating pulses to grow the material. In some embodiments, the pulse time of the second precursor may be greater than or about 0.5 seconds, greater than or about 1 second, greater than or about 2 seconds, greater than or about 3 seconds, greater than or about 4 seconds, greater than or about 5 seconds, greater than or about 10 seconds, greater than or about 20 seconds, greater than or about 40 seconds, greater than or about 60 seconds, greater than or about 80 seconds, greater than or about 100 seconds, or more.

In some embodiments, the first precursor may be pulsed for longer periods of time than the third precursor. By increasing the residence time of the first precursor, improved adhesion may be produced across the substrate 205 or one or more materials 210. The third precursor may then more readily react with the ligands of the first precursor, and thus the third precursor may be pulsed for less time, which may improve throughput. For example, in some embodiments, the third precursor may be pulsed for less than or about 90% of the time the first precursor is pulsed.

The third precursor may also be pulsed for less than or about 80% of the time the first precursor is pulsed, less than or about 70% of the time the first precursor is pulsed, less than or about 60% of the time the first precursor is pulsed, less than or about 50% of the time the first precursor is pulsed, less than or about 40% of the time the first precursor is pulsed, less than or about 30% of the time the first precursor is pulsed, or less.

In some embodiments, the second precursor may be pulsed for longer periods of time than the third precursor. For example, in some embodiments, the third precursor may be pulsed for less than or about 90% of the time the second precursor is pulsed. The third precursor may also be pulsed for less than or about 80% of the time the second precursor is pulsed, less than or about 70% of the time the second precursor is pulsed, less than or about 60% of the time the second precursor is pulsed, less than or about 50% of the time the second precursor is pulsed, less than or about 40% of the time the second precursor is pulsed, less than or about 30% of the time the second precursor is pulsed, or less.

In some embodiments, the third precursor may be pulsed for longer periods of time than the second precursor. For example, in some embodiments, the second precursor may be pulsed for less than or about 90% of the time the third precursor is pulsed. The second precursor may also be pulsed for less than or about 80% of the time the third precursor is pulsed, less than or about 70% of the time the third precursor is pulsed, less than or about 60% of the time the third precursor is pulsed, less than or about 50% of the time the third precursor is pulsed, less than or about 40% of the time the third precursor is pulsed, less than or about 30% of the time the third precursor is pulsed, or less.

The methods described herein may also include an operation to purge or remove the third precursor from the processing region following the formation of the silicon-and-oxygen-containing material 230. The methods described herein may include halting a flow of the third precursor prior to purging the third precursor from the semiconductor processing chamber. The third precursor may be removed by pumping them out of the processing region for a period of time ranging from about 10 seconds to about 100 seconds. Additional exemplary time ranges may include about 20 seconds to about 50 seconds, and 25 seconds to about 45 seconds, among other exemplary time ranges. However, in some embodiments, increased purge time may begin to remove reactive sites, which may reduce uniform formation. Accordingly, in some embodiments the purge may be performed for less than or about 60 seconds, and may be performed for less than or about 50 seconds, less than or about 40 seconds, less than or about 30 seconds, or less. In some embodiments, a purge gas may be introduced to the processing region to assist in the removal of the effluents. Exemplary purge gases include helium and nitrogen, among other purge gases.

In embodiments, there may be a determination of whether a target thickness of the as-deposited material on the substrate 205 or one or more materials 210 has been achieved following one or more cycles of forming the silicon-and-oxygen-containing material 230. If a target thickness of the as-deposited material has not been achieved, another cycle of providing the first precursor, third precursor, and the second precursor may be performed. If a target thickness of the as-deposited material has been achieved, another cycle of providing the first precursor, the third precursor, and the second precursor may not be started. Exemplary numbers of cycles for the formation of the silicon-and-oxygen-containing material 230 may include 1 cycle, or may include greater than 2 cycles, 5 cycles, 10 cycles, 25 cycles, 50 cycles, 100 cycles, 1000 cycles, 10000 cycles or more. Additional exemplary ranges for the number of cycles may include 50 cycles to 2000 cycles, 50 cycles to 1000 cycles, and 100 cycles to 750 cycles, among other exemplary ranges. Exemplary ranges of target thickness to discontinue further cycles of forming silicon-and-oxygen-containing material 230 include less than or about 1.0 microns. Additional exemplary thickness ranges may include less than or about 1.0 microns, less than or about 0.9 microns, less than or about 0.8 microns, less than or about 0.7 microns, less than or about 0.6 microns, less than or about 0.5 microns, less than or about 0.4 microns, less than or about 0.3 microns, less than or about 0.2 microns, less than or about 0.1 microns, or less, including any fraction of any of the stated numbers.

FIG. 8 illustrates an example flowchart 800 of a method of filling a feature on a semiconductor substrate as described herein. This method may be carried out by the controller that generates the signals for controlling the processing chamber and other elements as illustrated above in FIGS. 2-6. This method may be carried out by a controller having processors that execute instructions to perform these operations.

The method may include performing a process to fill the feature on the semiconductor substrate in a semiconductor processing chamber. The process can include repeatedly performing second operations as described herein. For example, the second operations can be repeated for a number of cycles as described herein. Additionally, parts of the second operations can be repeated for different numbers of cycles such that one part of the second operations can be repeated for a first number of cycles while a second part of the second operations can be repeated for a second number of cycles.

The second operations may include providing a silicon-containing precursor (802) to a semiconductor processing chamber (for example, the processing chamber 100 of FIG. 1) as described in relation to at least FIGS. 2A-2D. The silicon-containing precursor can be a first precursor as described herein.

The second operations may include contacting the substrate with the silicon-containing precursor to form a silicon-containing material within the feature defined on the substrate (804) as described herein. Forming the silicon-containing material within the feature can include forming an atomic layer of silicon on an exposed surface of the feature. The exposed surface of the feature can include two or more sides of the feature, for example sides that are opposite of each other.

The second operations may include purging the semiconductor processing chamber (806) as described herein. Purging the semiconductor processing chamber of the silicon-containing precursor can allow for the use of other precursors during the process to fill the feature on the semiconductor substrate.

The second operations may include providing an oxygen-containing precursor (808) as described herein. Providing the oxygen-containing precursor can cause a gap in the feature to close by causing a first side of the silicon-and-oxygen-containing material within the feature to bond with a second side of the silicon-and-oxygen-containing material within the feature as described in relation to at least FIGS. 3A-3B. In some embodiments, the oxygen-containing precursor can include, mostly include, or solely be a plasma. In some embodiments, the oxygen-containing precursor can include, mostly include, or solely be a gas.

The second operations may include contacting the substrate with the oxygen-and-hydrogen-containing precursor to form a silicon-and-oxygen-containing material within the feature defined on the substrate (810) as described herein. Forming the silicon-and-oxygen-containing material within the feature can include providing oxygen to the atomic layer of silicon. In some embodiments, the feature can be characterized by an aspect ratio of greater than or about 10:1 as described herein.

The second operations may include providing an oxygen-and-hydrogen-containing precursor (812) as described herein. In some embodiments, the oxygen-and-hydrogen-containing precursor can include O₂ and H₂. In some embodiments, the oxygen-and-hydrogen-containing precursor can include H₂O₂. In some embodiments, the oxygen-and-hydrogen-containing precursor can include H₂O. In some embodiments, the oxygen-and-hydrogen-containing precursor can include, mostly include, or solely be a plasma. In some embodiments, the oxygen-and-hydrogen-containing precursor can include, mostly include, or solely be a gas.

In some embodiments, the process can be performed at a temperature greater than or about 400° C. as described herein. Exemplary temperatures for the substrate, processing chamber, and/or precursors during the operations described herein may be greater than or about 400° C., greater than or about 425° C., greater than or about 450° C., greater than or about 475° C., greater than or about 500° C., greater than or about 525° C., greater than or about 550° C., greater than or about 575° C., greater than or about 600° C., greater than or about 625° C., greater than or about 650° C., greater than or about 675° C., greater than or about 700° C., greater than or about 725° C., greater than or about 750° C., greater than or about 775° C., greater than or about 800° C., greater than or about 825° C., greater than or about 850° C., greater than or about 875° C., greater than or about 900° C., greater than or about 925° C., greater than or about 950° C., greater than or about 975° C., greater than or about 1000° C., or higher. In some embodiments, exemplary temperatures can range from 400° C.-1000° C. In some embodiments, exemplary temperatures can range from 400° C.-700° C. In some embodiments, exemplary temperatures can range from 600° C.-1000° C.

In some embodiments, the process can be performed at a pressure level is greater than or about 2 Torr as described herein. In some embodiments, the pressures in the processing region may range from 2 to 10 Torr. In embodiments, the pressure may be less than or about 10 Torr, such as less than or about 9 Torr, less than or about 8 Torr, less than or about 7 Torr, less than or about 6 Torr, less than or about 5 Torr, less than or about 4 Torr, less than or about 3 Torr, less than or about 2 Torr, less than or about 1 Torr, or less.

The second operations may include contacting the substrate with the oxygen-and-hydrogen-containing precursor (814) as described herein. Contacting the silicon-and-oxygen-containing precursor with the oxygen-and-hydrogen-containing precursor can cause a gap to close by causing a first side of the silicon-and-oxygen-containing material within the feature to bond with a second side of the silicon-and-oxygen-containing material within the feature.

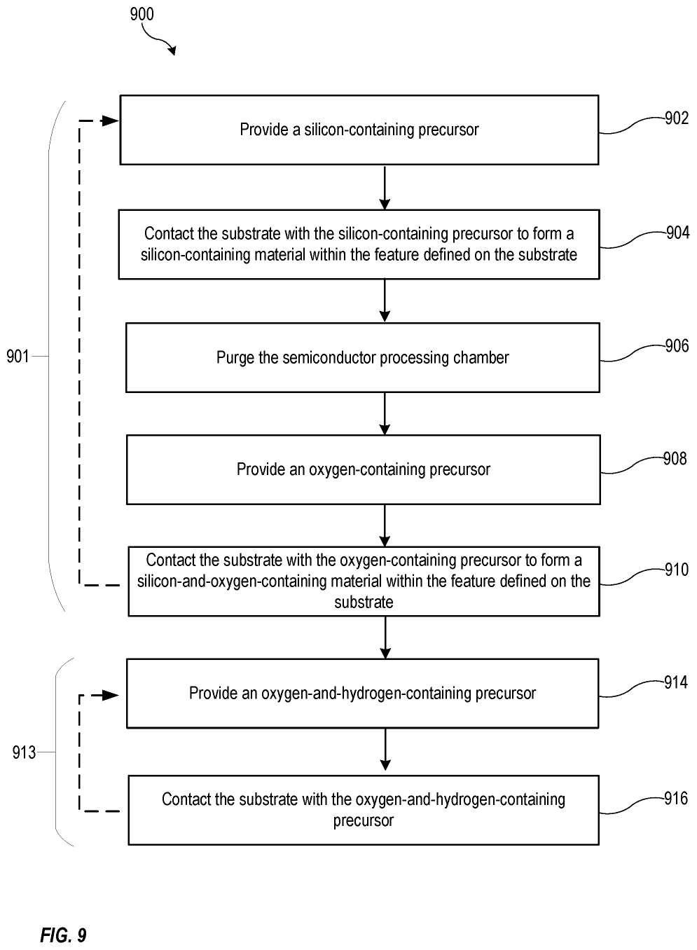

In relation to FIG. 9, as well as FIGS. 2A-2D and 3A-3B, the methods described herein for gapfilling seams may, in some embodiments, include third operations and fourth operations. The third operations may precede the fourth operations. The third operations may provide the first precursor and the third precursor (for example, the oxygen-containing precursor), but not the second precursor (for example, the oxygen-and-hydrogen-containing precursor). For example, after the removal of the first precursor, the third precursor may be provided to the semiconductor processing chamber in much the same way as the second precursor was described as being provided in relation to FIG. 2C. However, in the third operations, the second precursor is not provided to the semiconductor processing chamber as described in relation to FIG. 2C.

In some embodiments, a plasma of the third precursor may be generated. It is also contemplated that a plasma of the third precursor may be generated prior to providing the plasma of the third precursor to the semiconductor processing chamber. In some embodiments, a plasma of the second precursor may be generated. It is also contemplated that a plasma of the second precursor may be generated prior to providing the plasma of the second precursor to the semiconductor processing chamber.

The third precursor may have at least one reactive group that can form bonds with unreacted reactive groups of the first precursor that formed the silicon-containing material 220. Molecules of the third precursor may react with the unreacted reactive groups of the first precursor to form bonds linking molecules of the third precursor to molecules of the first precursor 215. The reactions between molecules of the third precursor and molecules of the first precursor 215 may continue until most or all the unreacted reactive groups on molecules of the first precursor 215 have reacted with molecules of the third precursor. As shown in FIG. 2D, the contact between the third precursor and the silicon-containing material 220 may form a silicon-and-oxygen-containing material 230, such as SiO. The formation of the silicon-and-oxygen-containing material 230 may block further reaction between molecules of the third precursor 225 in the third precursor effluent and the silicon-and-oxygen-containing material 220.

Similar to the first precursor and the second precursor, the third precursor may remain in the processing region for a period of time to nearly or completely form the silicon-and-oxygen-containing material 230. As previously discussed, to form silicon-and-oxygen-containing material according to embodiments of the present technology, precursors may be delivered in alternating pulses to grow the material. In some embodiments, the pulse time of the second precursor may be greater than or about 0.5 seconds, greater than or about 1 second, greater than or about 2 seconds, greater than or about 3 seconds, greater than or about 4 seconds, greater than or about 5 seconds, greater than or about 10 seconds, greater than or about 20 seconds, greater than or about 40 seconds, greater than or about 60 seconds, greater than or about 80 seconds, greater than or about 100 seconds, or more.

In some embodiments, the first precursor may be pulsed for longer periods of time than the third precursor. By increasing the residence time of the first precursor, improved adhesion may be produced across the substrate 205 or one or more materials 210. The third precursor may then more readily react with the ligands of the first precursor, and thus the third precursor may be pulsed for less time, which may improve throughput. For example, in some embodiments, the third precursor may be pulsed for less than or about 90% of the time the first precursor is pulsed. The third precursor may also be pulsed for less than or about 80% of the time the first precursor is pulsed, less than or about 70% of the time the first precursor is pulsed, less than or about 60% of the time the first precursor is pulsed, less than or about 50% of the time the first precursor is pulsed, less than or about 40% of the time the first precursor is pulsed, less than or about 30% of the time the first precursor is pulsed, or less.

The methods described herein may also include an operation to purge or remove the third precursor from the processing region following the formation of the silicon-and-oxygen-containing material 230. The methods described herein may include halting a flow of the third precursor prior to purging the third precursor from the semiconductor processing chamber. The third precursor may be removed by pumping them out of the processing region for a period of time ranging from about 10 seconds to about 100 seconds. Additional exemplary time ranges may include about 20 seconds to about 50 seconds, and 25 seconds to about 45 seconds, among other exemplary time ranges. However, in some embodiments, increased purge time may begin to remove reactive sites, which may reduce uniform formation. Accordingly, in some embodiments the purge may be performed for less than or about 60 seconds, and may be performed for less than or about 50 seconds, less than or about 40 seconds, less than or about 30 seconds, or less. In some embodiments, a purge gas may be introduced to the processing region to assist in the removal of the effluents. Exemplary purge gases include helium and nitrogen, among other purge gases.

In relation to FIGS. 7-8, in some embodiments, the method described in relation to flowchart 700 and the method described in relation to flowchart 800 include the third operations as described herein. In some embodiments, the third operations as described herein can precede the first operations as described in relation to FIG. 7. For example, the third operations can be repeatedly performed prior to repeatedly performing the first operations. In some embodiments, the percentage of total cycles for the first operations and the third operations can be apportioned such that the first operations occur for about 90% of the total cycles, such that the first operations occur for about 80% of the total cycles, such that the first operations occur for about 70% of the total cycles, such that the first operations occur for about 60% of the total cycles, such that the first operations occur for about 50% of the total cycles, such that the first operations occur for about 40% of the total cycles, such that the first operations occur for about 30% of the total cycles, such that the first operations occur for about 20% of the total cycles, such that the first operations occur for about 10% of the total cycles, or less.

In some embodiments, the third operations as described herein can precede the second operations as described in relation to FIG. 8. For example, the third operations can be repeatedly performed prior to repeatedly performing the second operations. In some embodiments, the percentage of total cycles for the second operations and the third operations can be apportioned such that the second operations occur for about 90% of the total cycles, such that the second operations occur for about 80% of the total cycles, such that the second operations occur for about 70% of the total cycles, such that the second operations occur for about 60% of the total cycles, such that the second operations occur for about 50% of the total cycles, such that the second operations occur for about 40% of the total cycles, such that the second operations occur for about 30% of the total cycles, such that the second operations occur for about 20% of the total cycles, such that the second operations occur for about 10% of the total cycles, or less.

The fourth operations may provide the second precursor (for example, the oxygen-and-hydrogen-containing precursor). For example, the second precursor may be provided to the semiconductor processing chamber in much the same way as the second precursor was described as being provided in relation to FIG. 2C. However, in the fourth operations, the first precursor may not be provided to the semiconductor processing chamber as described in relation to FIG. 2C.

In some embodiments, in the fourth operations, the first precursor can be provided to the semiconductor processing chamber as described in relation to FIG. 2C. If the fourth operations provides the first precursor, the fourth operations can also include contacting the substrate and/or silicon-and-oxygen-containing material with the first precursor as described herein, such as in relation to FIG. 2A. Similarly, the first precursor can be purged as described herein, such as in relation to FIG. 2B.

In some embodiments, the methods described herein for gapfilling seams may include a first number of cycles of the third operations followed by a second number of cycles of the fourth operations. For example, the third operations may operate to provide the first precursor to the semiconductor processing chamber and then provide the third precursor to the semiconductor processing chamber for a first number of cycles. Then the fourth operations may operate to provide the first precursor to the semiconductor processing chamber and then provide the second precursor to the semiconductor processing chamber for a second number of cycles. In another example, the third operations may operate to provide the first precursor to the semiconductor processing chamber and then provide the third precursor to the semiconductor processing chamber for a first number of cycles. Then the fourth operations may operate to provide the first precursor to the semiconductor processing chamber, then provide the third precursor to the semiconductor processing chamber, and then provide the second precursor to the semiconductor processing chamber for a second number of cycles.

Additionally, parts of the third operations can be repeated for different numbers of cycles such that one part of the third operations can be repeated for a first number of cycles while a second part of the third operations can be repeated for a second number of cycles. Additionally, parts of the fourth operations can be repeated for different numbers of cycles such that one part of the fourth operations can be repeated for a first number of cycles while a second part of the fourth operations can be repeated for a second number of cycles.

The number of cycles for the fourth operations and the number of cycles for the third operations can be determined by any fourth. In some embodiments, the percentage of total cycles for the third operations and the fourth operations can be apportioned such that the third operations occur for about 99% of the total cycles, such that the third operations occur for about 98% of the total cycles, such that the third operations occur for about 97% of the total cycles, such that the third operations occur for about 96% of the total cycles, such that the third operations occur for about 95% of the total cycles, such that the third operations occur for about 90% of the total cycles, such that the third operations occur for about 80% of the total cycles, such that the third operations occur for about 70% of the total cycles, such that the third operations occur for about 60% of the total cycles, such that the third operations occur for about 50% of the total cycles, such that the third operations occur for about 40% of the total cycles, such that the third operations occur for about 30% of the total cycles, such that the third operations occur for about 20% of the total cycles, such that the third operations occur for about 10% of the total cycles, or less.

In some embodiments, there may be a determination of whether a target thickness of the as-deposited material on the substrate 205 or one or more materials 210 has been achieved following one or more cycles of forming the silicon-and-oxygen-containing material 230. If a target thickness of the as-deposited material has not been achieved, another cycle of providing the first precursor and third precursor may be performed according to the third operations. If a target thickness of the as-deposited material has been achieved, another cycle of providing the first precursor and third precursor may not be started according to the third operations.

Alternatively, if a target thickness of the as-deposited material has not been achieved, another cycle of providing the first precursor and second precursor may be performed according to the fourth operations. If a target thickness of the as-deposited material has been achieved, another cycle of providing the first precursor and second precursor may not be started according to the fourth operations. Additionally, another cycle of the fourth operations may be started if the gap is not filled. Exemplary numbers of cycles for the formation of the silicon-and-oxygen-containing material 230 may include 1 cycle, or may include greater than 2 cycles, 5 cycles, 10 cycles, 25 cycles, 50 cycles, 100 cycles, 1000 cycles, 2000 cycles, 3000 cycles, 4000 cycles, 5000 cycles, 6000 cycles, 7000 cycles, 8000 cycles, 9000 cycles, 10000 cycles or more. Additional exemplary ranges for the number of cycles may include 50 cycles to 2000 cycles, 50 cycles to 1000 cycles, and 100 cycles to 750 cycles, 1000 to 2000 cycles, 2000 to 3000 cycles, 3000 to 4000 cycles, 4000 to 5000 cycles, 5000 to 6000 cycles, 6000 to 7000 cycles, 7000 to 8000 cycles, 8000 to 9000 cycles, 9000 to 10000 cycles, and/or any combination of these ranges. For example, some embodiments may use between 6000 and 8000 cycles for a 1 μm wide gap structure. Exemplary ranges of target thickness to discontinue further cycles of forming silicon-and-oxygen-containing material 230 include less than or about 1.0 microns. Additional exemplary thickness ranges may include less than or about 1.0 microns, less than or about 0.9 microns, less than or about 0.8 microns, less than or about 0.7 microns, less than or about 0.6 microns, less than or about 0.5 microns, less than or about 0.4 microns, less than or about 0.3 microns, less than or about 0.2 microns, less than or about 0.1 microns, or less, including any fraction of any of the stated numbers.

FIG. 9 illustrates an example flowchart 900 of a method of filling a feature on a semiconductor substrate as described herein. This method may be carried out by the controller that generates the signals for controlling the processing chamber and other elements as illustrated above in FIGS. 2-6. This method may be carried out by a controller having processors that execute instructions to perform these operations.

The method may include performing a process to fill the feature on the semiconductor substrate in a semiconductor processing chamber. The process can include repeatedly performing third operations (901) as described herein. For example, the third operations can be repeated for a number of cycles as described herein. Additionally, parts of the third operations can be repeated for different numbers of cycles such that one part of the third operations can be repeated for a first number of cycles while a second part of the third operations can be repeated for a second number of cycles. In some embodiments, the feature can be characterized by an aspect ratio of greater than or about 10:1 as described herein.

In some embodiments, the third operations can be performed at a first pressure level. In some embodiments, the first pressure level can be greater than or about 2 Torr as described herein. In some embodiments, the pressures in the processing region may range from 2 to 10 Torr. In embodiments, the pressure may be less than or about 10 Torr, such as less than or about 9 Torr, less than or about 8 Torr, less than or about 7 Torr, less than or about 6 Torr, less than or about 5 Torr, less than or about 4 Torr, less than or about 3 Torr, less than or about 2 Torr, less than or about 1 Torr, or less.

In some embodiments, the third operations can be performed at a first temperature. In some embodiments, the first temperature can be a temperature greater than or about 400° C. as described herein. In some embodiments, the third operations can be performed at a temperature greater than or about 400° C. as described herein. Exemplary temperatures for the substrate, processing chamber, and/or precursors during the operations described herein may be greater than or about 400° C., greater than or about 425° C., greater than or about 450° C., greater than or about 475° C., greater than or about 500° C., greater than or about 525° C., greater than or about 550° C., greater than or about 575° C., greater than or about 600° C., greater than or about 625° C., greater than or about 650° C., greater than or about 675° C., greater than or about 700° C., greater than or about 725° C., greater than or about 750° C., greater than or about 775° C., greater than or about 800° C., greater than or about 825° C., greater than or about 850° C., greater than or about 875° C., greater than or about 900° C., greater than or about 925° C., greater than or about 950° C., greater than or about 975° C., greater than or about 1000° C., or higher. In some embodiments, exemplary temperatures can range from 400° C.-1000° C. In some embodiments, exemplary temperatures can range from 400° C.-700° C. In some embodiments, exemplary temperatures can range from 600° C.-1000° C.

The third operations may include providing a silicon-containing precursor (902) to a semiconductor processing chamber (for example, the processing chamber 100 of FIG. 1) as described in relation to at least FIGS. 2A-2D. The silicon-containing precursor can be a first precursor as described herein.

The third operations may include contacting the substrate with the silicon-containing precursor to form a silicon-containing material within the feature defined on the substrate (904) as described herein. Forming the silicon-containing material within the feature can include forming an atomic layer of silicon on an exposed surface of the feature. The exposed surface of the feature can include two or more sides of the feature, for example sides that are opposite of each other.

The third operations may include purging the semiconductor processing chamber (906) as described herein. Purging the semiconductor processing chamber of the silicon-containing precursor can allow for the use of other precursors during the process to fill the feature on the semiconductor substrate.

The third operations may include providing an oxygen-containing precursor (908) as described herein. Providing the oxygen-containing precursor can cause a gap in the feature to close by causing a first side of the silicon-and-oxygen-containing material within the feature to bond with a second side of the silicon-and-oxygen-containing material within the feature as described in relation to at least FIGS. 3A-3B. In some embodiments, the oxygen-containing precursor can include, mostly include, or solely be a plasma. In some embodiments, the oxygen-containing precursor can include, mostly include, or solely be a gas.

The third operations may include contacting the substrate with the oxygen-and-hydrogen-containing precursor to form a silicon-and-oxygen-containing material within the feature defined on the substrate (910) as described herein. Forming the silicon-and-oxygen-containing material within the feature can include providing oxygen to the atomic layer of silicon.

The process can also include repeatedly performing fourth operations (913) as described herein. For example, the fourth operations can be repeated for a number of cycles as described herein. Additionally, parts of the fourth operations can be repeated for different numbers of cycles such that one part of the fourth operations can be repeated for a first number of cycles while a second part of the third operations can be repeated for a second number of cycles. In some embodiments, the feature can be characterized by an aspect ratio of greater than or about 10:1 as described herein.

In some embodiments, the fourth operations can be performed at a second pressure level. In some embodiments, the second pressure level can be about between sub atmospheric pressures and atmospheric pressure. For example, pressures may range between about 1-10 Torr.

In some embodiments, the fourth operations can be performed at a second temperature. In some embodiments, the second temperature can be a temperature greater than or about 400° C. as described herein. In some embodiments, first temperature and the second temperature can be different. In some embodiments, the fourth operations can be performed at a temperature greater than or about 400° C. as described herein. Exemplary temperatures for the substrate, processing chamber, and/or precursors during the operations described herein may be greater than or about 400° C., greater than or about 425° C., greater than or about 450° C., greater than or about 475° C., greater than or about 500° C., greater than or about 525° C., greater than or about 550° C., greater than or about 575° C., greater than or about 600° C., greater than or about 625° C., greater than or about 650° C., greater than or about 675° C., greater than or about 700° C., greater than or about 725° C., greater than or about 750° C., greater than or about 775° C., greater than or about 800° C., greater than or about 825° C., greater than or about 850° C., greater than or about 875° C., greater than or about 900° C., greater than or about 925° C., greater than or about 950° C., greater than or about 975° C., greater than or about 1000° C., or higher. In some embodiments, exemplary temperatures can range from 400° C.-1000° C. In some embodiments, exemplary temperatures can range from 400° C.-700° C. In some embodiments, exemplary temperatures can range from 600° C.-1000° C.

The fourth operations may include providing an oxygen-and-hydrogen-containing precursor (914) as described herein. In some embodiments, the oxygen-and-hydrogen-containing precursor can include O₂ and H₂. In some embodiments, the oxygen-and-hydrogen-containing precursor can include H₂O. In some embodiments, the oxygen-and-hydrogen-containing precursor can include H₂O. In some embodiments, the oxygen-and-hydrogen-containing precursor can include, mostly include, or solely be a plasma. In some embodiments, the oxygen-and-hydrogen-containing precursor can include, mostly include, or solely be a gas.

The fourth operations may include contacting the substrate with the oxygen-and-hydrogen-containing precursor (916) as described herein. Contacting the silicon-and-oxygen-containing precursor with the oxygen-and-hydrogen-containing precursor can cause a gap to close by causing a first side of the silicon-and-oxygen-containing material within the feature to bond with a second side of the silicon-and-oxygen-containing material within the feature.

As described herein, in some embodiments, the fourth operations can also include may include providing a silicon-containing precursor to a semiconductor processing chamber. As described herein, in some embodiments, the fourth operations can include contacting the substrate and/or the silicon-and-oxygen-containing material with the silicon-containing precursor. As described herein, in some embodiments, the fourth operations can include purging the semiconductor processing chamber as described herein.

The first, second, third, and fourth operations as described in relation to FIGS. 7-9 can also be used in any combination in order to gapfill a seam.

In the preceding description, for the purposes of explanation, numerous details have been set forth in order to provide an understanding of various embodiments of the present technology. It will be apparent to one skilled in the art, however, that certain embodiments may be practiced without some of these details, or with additional details.

Having disclosed several embodiments, it will be recognized by those of skill in the art that various modifications, alternative constructions, and equivalents may be used without departing from the spirit of the embodiments. Additionally, a number of well-known processes and elements have not been described in order to avoid unnecessarily obscuring the present technology. Accordingly, the above description should not be taken as limiting the scope of the technology.

Where a range of values is provided, it is understood that each intervening value, to the smallest fraction of the unit of the lower limit, unless the context clearly dictates otherwise, between the upper and lower limits of that range is also specifically disclosed. Any narrower range between any stated values or unstated intervening values in a stated range and any other stated or intervening value in that stated range is encompassed. The upper and lower limits of those smaller ranges may independently be included or excluded in the range, and each range where either, neither, or both limits are included in the smaller ranges is also encompassed within the technology, subject to any specifically excluded limit in the stated range. Where the stated range includes one or both of the limits, ranges excluding either or both of those included limits are also included.

As used herein and in the appended claims, the singular forms “a”, “an”, and “the” include plural references unless the context clearly dictates otherwise. Thus, for example, reference to “a precursor” includes a plurality of such precursor, and reference to “the material” includes reference to one or more materials and equivalents thereof known to those skilled in the art, and so forth.

Also, the words “comprise(s)”, “comprising”, “contain(s)”, “containing”, “include(s)”, and “including”, when used in this specification and in the following claims, are intended to specify the presence of stated features, integers, components, or operations, but they do not preclude the presence or addition of one or more other features, integers, components, operations, acts, or groups.

1. A method of filling a feature on a semiconductor substrate, the method comprising:
performing a process to fill the feature on the semiconductor substrate in a semiconductor processing chamber, wherein the process comprises repeatedly performing first operations comprising:
providing a silicon-containing precursor;
contacting the substrate with the silicon-containing precursor to form a silicon-containing material within the feature defined on the substrate;
purging the semiconductor processing chamber;
providing an oxygen-and-hydrogen-containing precursor; and
contacting the substrate with the oxygen-and-hydrogen-containing precursor to form a silicon-and-oxygen-containing material within the feature defined on the substrate.

2. The method of claim 1, wherein providing the oxygen-and-hydrogen-containing precursor causes a gap in the feature to close by causing a first side of the silicon-and-oxygen-containing material within the feature to bond with a second side of the silicon-and-oxygen-containing material within the feature.

3. The method of claim 1, wherein forming the silicon-containing material within the feature includes forming an atomic layer of silicon on an exposed surface of the feature; and
wherein forming the silicon-and-oxygen-containing material within the feature includes providing oxygen to the atomic layer of silicon.

4. The method of claim 1, wherein the process to fill the feature further comprises repeatedly performing second operations prior to repeatedly performing first operations, wherein both the first operations and the second operations are done at about a first pressure level, the second operations comprising:
providing the silicon-containing precursor;
contacting the substrate with the silicon-containing precursor to form a silicon-containing material within the feature defined on the substrate;
purging the semiconductor processing chamber;
providing an oxygen-containing precursor; and
contacting the substrate with the oxygen-containing precursor to form a silicon-and-oxygen-containing material within the feature defined on the substrate.

5. The method of claim 4, wherein the first pressure level is greater than or about 2 Torr.

6. The method of claim 1, wherein the feature is characterized by an aspect ratio of greater than or about 10:1.

7. The method of claim 1, wherein the oxygen-and-hydrogen-containing precursor comprises O₂ and H₂.

8. The method of claim 1, wherein the oxygen-and-hydrogen-containing precursor comprises H₂O₂.

9. The method of claim 1, wherein the oxygen-and-hydrogen-containing precursor comprises H₂O.

10. A method of filling a feature on a semiconductor substrate, the method comprising:
performing a process to fill the feature on the semiconductor substrate in a semiconductor processing chamber, wherein the process comprises repeatedly performing first operations comprising:
providing a silicon-containing precursor;
contacting the substrate with the silicon-containing precursor to form a silicon-containing material within the feature defined on the substrate;
purging the semiconductor processing chamber;
providing an oxygen-containing precursor;
contacting the substrate with the oxygen-containing precursor to form a silicon-and-oxygen-containing material within the feature defined on the substrate;
providing an oxygen-and-hydrogen-containing precursor; and
contacting the silicon-and-oxygen-containing material with the oxygen-and-hydrogen-containing precursor.

11. The method of claim 10, wherein contacting the silicon-and-oxygen-containing material with the oxygen-and-hydrogen-containing precursor causes a gap in the feature to close by causing a first side of the silicon-and-oxygen-containing material within the feature to bond with a second side of the silicon-and-oxygen-containing material within the feature.

12. The method of claim 10, wherein the process to fill the feature further comprises repeatedly performing second operations prior to repeatedly performing first operations, the second operations comprising:
providing the silicon-containing precursor;
contacting the substrate with the silicon-containing precursor to form a silicon-containing material within the feature defined on the substrate;
purging the semiconductor processing chamber;
providing the oxygen-containing precursor; and
contacting the substrate with the oxygen-containing precursor to form a silicon-and-oxygen-containing material within the feature defined on the substrate.

13. The method of claim 10, wherein the process is performed at a temperature greater than or about 400° C.

14. The method of claim 10, wherein the oxygen-and-hydrogen-containing precursor comprises a plasma.

15. The method of claim 10, wherein the oxygen-and-hydrogen-containing precursor comprises a gas.

16. A method of filling a feature on a semiconductor substrate, the method comprising:
performing a process to fill the feature on the semiconductor substrate in a semiconductor processing chamber, wherein the process comprises repeatedly performing first operations at a first pressure level, the first operations comprising:
providing a silicon-containing precursor;
contacting the substrate with the silicon-containing precursor to form a silicon-containing material within the feature defined on the substrate;
purging the semiconductor processing chamber;
providing an oxygen-containing precursor; and
contacting the substrate with the oxygen-containing precursor to form a silicon-and-oxygen-containing material within the feature defined on the substrate; and
wherein the process to fill the feature further comprises repeatedly performing second operations at a second pressure level after repeatedly performing first operations, the second operations comprising:
providing an oxygen-and-hydrogen-containing precursor; and
contacting the silicon-and-oxygen-containing material with the oxygen-and-hydrogen-containing precursor.

17 The method of claim 16, wherein the first pressure level is about 2 Torr.

18. The method of claim 17, wherein the second pressure level is about atmospheric pressure.

19. The method of claim 16, wherein the second operations, prior to providing the oxygen-and-hydrogen-containing precursor, further comprise:
providing the silicon-containing precursor;
contacting the silicon-and-oxygen-containing material with the silicon-containing precursor to form a silicon-containing material within the feature; and
purging the semiconductor processing chamber.

20. The method of claim 16, wherein contacting the silicon-and-oxygen-containing material with the oxygen-and-hydrogen-containing precursor causes a gap in the feature to close by causing a first side of the silicon-and-oxygen-containing material within the feature to bond with a second side of the silicon-and-oxygen-containing material within the feature.
